(19) United States
(12) Patent Application Publication
(10) Pub. No.: US 2010/0171202 A1
(43) Pub. Date: Jul. 8, 2010

(54) Method of securely data protecting arrangement for electronic device

(76) Inventors: WeiCheng Tian, ShangHai (CN); Yi Dong, Shanghai (CN)

Correspondence Address: DAVID AND RAYMOND PATENT FIRM, 108 N. YNEZ AVE., SUITE 128, MONTEREY PARK, CA, 91754, US

(21) Appl. No.: 12/319,553

(22) Filed: Jan. 7, 2009

(51) Int. Cl. H01L 23/02

(52) U.S. Cl. 257/679; 257/E23.18

(57) ABSTRACT

A method of securely data protection for an electronic device includes the steps of: enclosing a core circuit module of the electronic within a protection element to form a protection circuit surrounding the core circuit module; operatively linking a detective circuit between the protection element and the core circuit module; and activating the detective circuit in case of a hack of the electronic device, such that when the electronic device is broken to access the core circuit module through the protection element, the detective circuit is activated to block data information saved in the core circuit module from being access.

### BACKGROUND OF THE PRESENT INVENTION

1. Field of Invention

The present invention relates to an arrangement for protecting the information saved in an electronic device, and more particularly to an arrangement of an electronic device for securely protecting the information of the electronic device from being stolen.

2. Description of Related Arts

Electronic devices such as personal computer, cell phone, or portable credit card machine, which is used in those individual stores such as a restaurant, are playing an important role in the electronic, computerization era. People are using the electronic devices for saving personal information or doing business transactions. Take a personal computer for example, password information of an email account are saved in the personal computer. A credit card machine, as another example, is widely used in most of individual stores for the transaction among customers, stores, and a bank. The information that inputted in the credit card machine for the transaction purpose may be illegally stolen by using any external forces or electronic devices to invade into the circuit board of the credit card machine so as to obtain the information saved in the memory unit of the circuit board. Though those electronic devices provide an easier and more convenience way of life style, how to protect those important personal information from being illegally obtained for any illegal purposes is a main concern.

### SUMMARY OF THE PRESENT INVENTION

A main object of the present invention is to provide a securely data protecting arrangement for an electronic device, so that when the electronic device is broke to get any information from a data unit of the electronic device, a detective circuit of the electronic device is automatically activated to erase the information saved in the data unit.

Another object of the present invention is to provide a securely data protecting arrangement for an electronic device, wherein the detective circuit for erasing or destroying the information saved in the data unit of the electronic device is automatically activated when a resistor, a capacitor, a current, or a voltage signal is changed, so as to protect the data unit from being stolen by an external and unexpected force such as opening an outer casing or penetrating the display module to get the information of the electronic device.

Another object of the present invention is to provide a securely data protecting arrangement for an electronic device, wherein a protection layer is integrally affixing to the display module and electrically connecting to the detective circuit, so that when the display module is being penetrated, the protection layer automatically activates the detective circuit to erase the information saved in the data unit.

Another object of the present invention is to provide a securely data protecting arrangement for an electronic device, wherein a plurality of conductive wires are provided to form the protection layer, wherein the conductive wires are made by a transparent material having the electrical conductivity such as ITO.

Another object of the present invention is to provide a securely data protecting arrangement for an electronic device, wherein the display module comprises a liquid crystal display (LCD) and a touch screen provided at an upper surface of the LCD, so that the display module is able to communicate and control the electronic device, so as to input and output the data information.

Another object of the present invention is to provided a securely data protecting arrangement for an electronic device, wherein the protection layer has an area equal or larger than the area of the display module, such that the protection layer can fully cover the display module to prevent any invasion from any dead space of the display module which is non-covered by the protection layer.

Another object of the present invention is to provide a securely data protecting arrangement for an electronic device, wherein a core element enclosure is provided for enclose a core circuit module of the electronic device, wherein the core element enclosure is electrically connecting to the detective circuit, such that when the core element enclosure is broke or removed from the core circuit module, the detective circuit is activated to erase the information in the data unit.

Accordingly, in order to accomplish the above objects, the present invention provides a method of securely data protection for an electronic device, comprising:

(a) enclosing a core circuit module of the electronic within a protection element to form a protection circuit surrounding the core circuit module;

(b) operatively linking a detective circuit between the protection element and the core circuit module; and

(c) activating the detective circuit in case of a hack of the electronic device, such that when the electronic device is broken to access the core circuit module through the protection element, the detective circuit is activated to block data information saved in the core circuit module from being access.

In addition, the present invention also provides a protection arrangement incorporating with the electronic device, comprising:

a protection element enclosing the core circuit module to form a protection circuit surrounding the core circuit module; and

a detective circuit operatively linking between the protection element and the core circuit module, wherein when the electronic device is broken to access the core circuit module through the protection element, the detective circuit is automatically activated to block data information saved in the core circuit module from being access.

These and other objectives, features, and advantages of the present invention will become apparent from the following detailed description, the accompanying drawings, and the appended claims.

### BRIEF DESCRIPTION OF THE DRAWINGS

FIG. 1A is a sectional view of a securely data protecting arrangement of the electronic device according to a preferred embodiment of the present invention.

FIG. 1B is a sectional view of a display module of the securely data protecting arrangement of the electronic device according to a preferred embodiment of the present invention, illustrating a protection layer provided on a top surface of the display module.

FIG. 1C is a sectional view of a display module of the securely data protecting arrangement of the electronic device according to a preferred embodiment of the present invention, illustrating the protection layer provided on a bottom surface of the display module.

FIG. 2 is an exploded view of the securely data protecting arrangement of the electronic device according to the above preferred embodiment of the present invention.

FIG. 3 is a partially enlarged view of a protection layer of the securely data protecting arrangement of the electronic device according to the above preferred embodiment of the present invention.

FIG. 4A is a perspective view of an outer casing incorporating with the securely data protecting arrangement of the electronic device according to the above preferred embodiment of the present invention.

FIG. 4B is a perspective exploded view of the outer casing incorporating with the securely data protecting arrangement of the electronic device according to the above preferred embodiment of the present invention.

FIG. 5 is a block diagram of a method of the securely data protecting arrangement of the electronic device according to the above preferred embodiment of the present invention.

FIG. 6 is a partially enlarged view of a protection layer of the securely data protecting arrangement of the electronic device according to a first alternative of the above preferred embodiment of the present invention.

FIG. 7 is a partially enlarged view of a protection layer of the securely data protecting arrangement of the electronic device according to a second alternative of the above preferred embodiment of the present invention.

### DETAILED DESCRIPTION OF THE PREFERRED EMBODIMENT

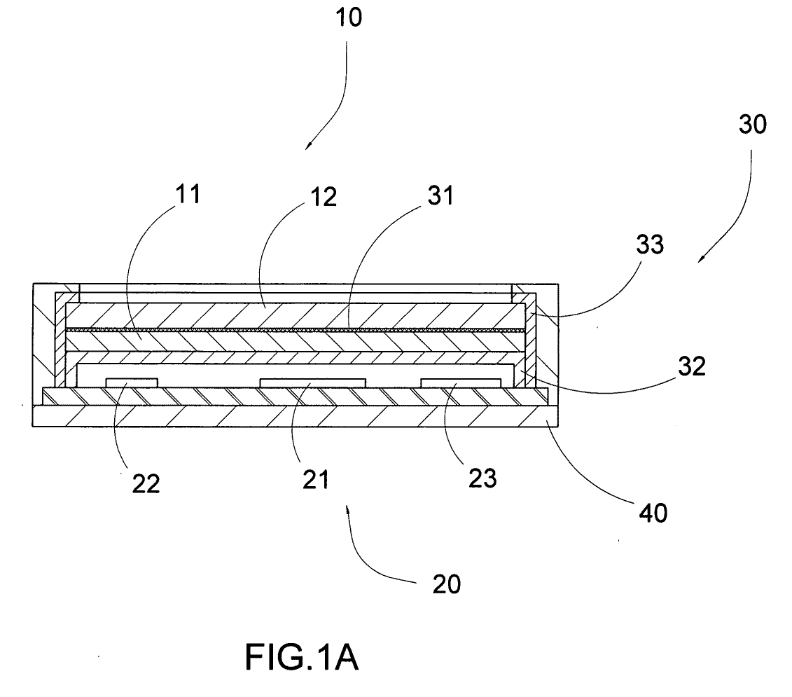

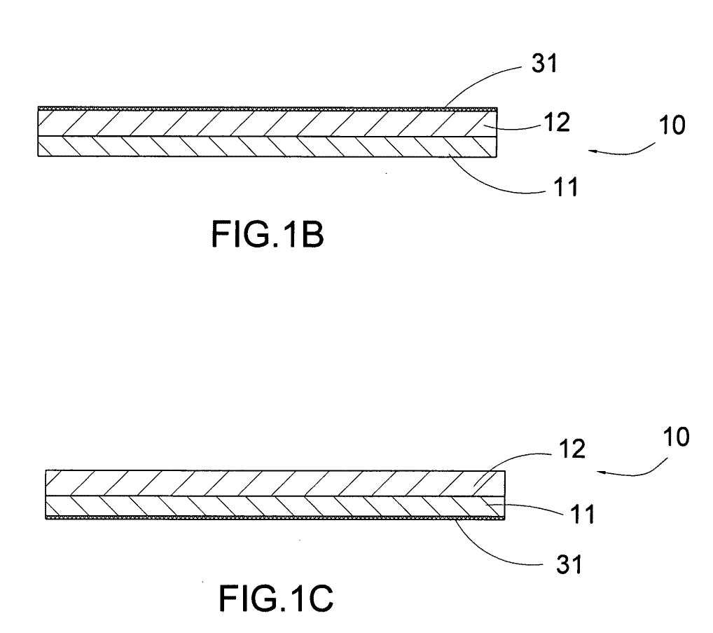

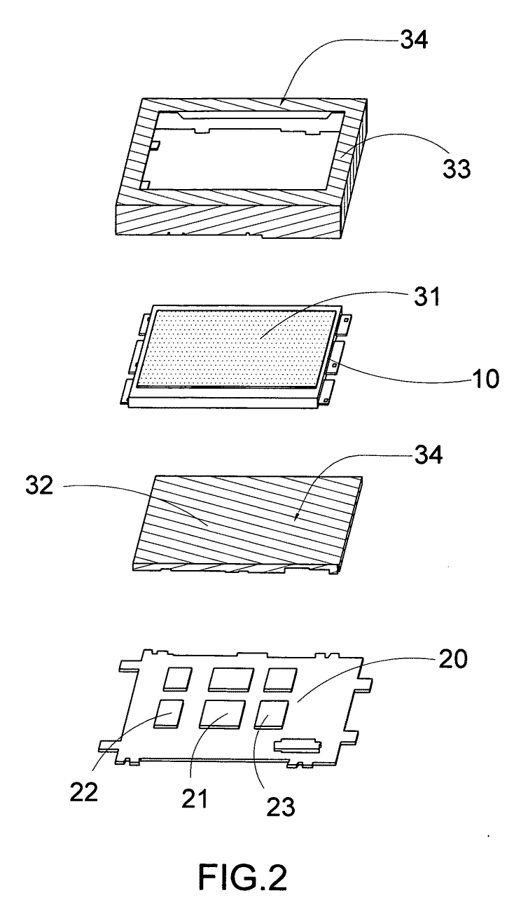

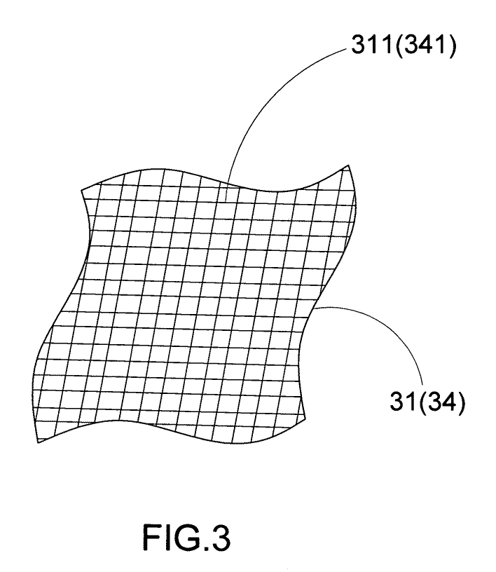

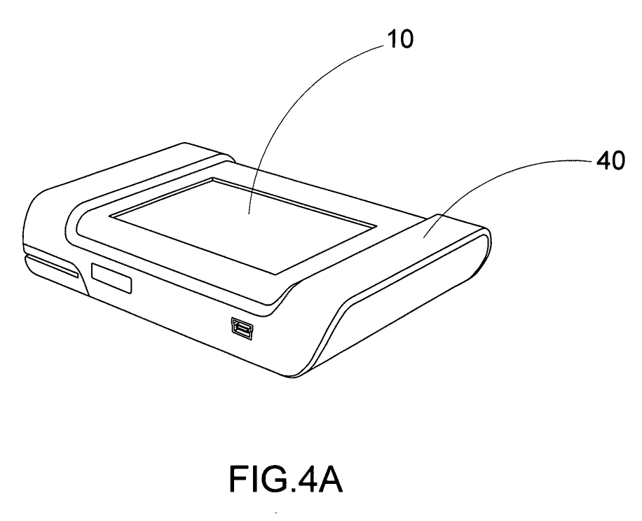

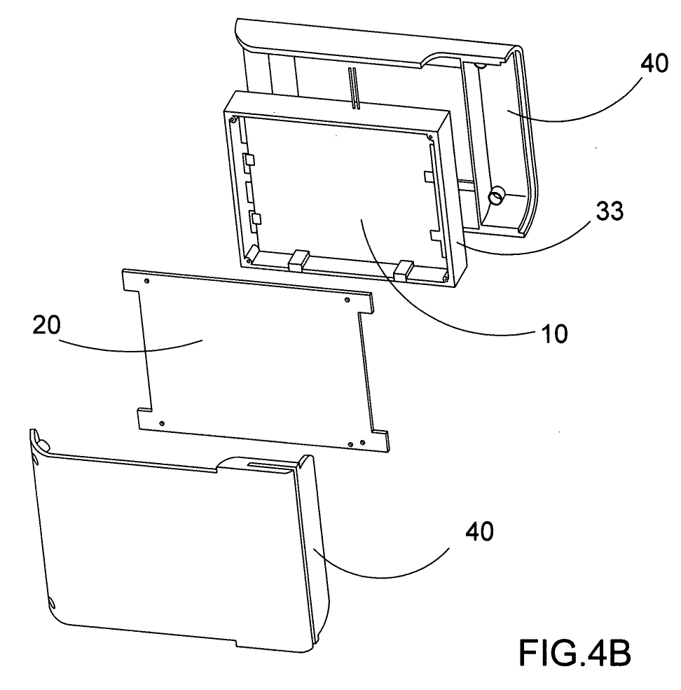

Referring to FIGS. 1 to 5 of the drawings, an electronic device according to a preferred embodiment of the present invention is illustrated, wherein the electronic device comprises a core circuit module 20 for saving data information and a display module 10 operatively connecting to the core circuit module 20. Accordingly, the core circuit module 20 comprises a CPU 21 and a data unit 23 controllably operated by the CPU for accessing the data information.

The electronic device further comprises a protection arrangement, which comprises a protection element 30 enclosing the core circuit module 20 to form a protection circuit surrounding the core circuit module 20, and a detective circuit 22 operatively linking between the protection element 30 and the core circuit module 20, wherein when the electronic device is broken to access the core circuit module 20 through the protection element 30 to physically interfere with the protection circuit, the detective circuit 22 is automatically activated to block data information saved in the core circuit module 20 from being access.

The protection element 30 has a protection layer 31 located above the core circuit module 20 and provided for incorporating with the display module 10, wherein the protection layer 31 of the display module 10 is electrically connecting to the core circuit module 20 of the electronic device, so that when the display module 10 is penetrated to break into the core circuit module 20 of the electronic device to physically interfere with the protection circuit, the protection layer 31 of the protection element 30 will activate the detective circuit 22 to destroy the data unit 23 through the CPU 21, so as to protect an data information saved in the data unit 23 from being stolen.

Accordingly, the detective circuit 22 is electrically coupled with the core circuit module 20 as one integral component, and is a data erasing circuit that when the detective circuit 22 is activated, the data information saved in the core circuit module 20 is automatically erased. The data information can be permanently erased in the core circuit module 20 or temporarily erased until a permission of access of the core circuit module 20 is obtained. Alternatively, when the detective circuit 22 is activated, the data information saved in the core circuit module 20 will be automatically frozen to prevent any access of the core circuit module 20.

The display module 10 comprises a screen panel 11 electrically connecting with the core circuit module 10 and a transparent screen 12 for covering and protecting the screen panel 11, wherein the display module 10 has a viewable area for a user to view information from the display module 10. Preferably, the transparent screen 12 of the display module 10 further has a touch screen function provided for inputting information for communicating and controlling the core circuit module 20 of the electronic device, so that the information can be conveniently inputted or/and outputted through the display module 10 and saved in the data unit 23. In order words, when the user presses to touch the display module 10, an resistor or an capacitor is changed to send an electronic signal, in such manner that the information can be inputted or/and outputted from the core circuit module 20 of the electronic device.

It is appreciated that the transparent screen 12 having the touch screen function provided for inputting data information of the electronic device avoids a circuit layout of conventional key board connecting to a circuit board of the electronic device, so that without the circuit layout of the conventional key board, the touch screen function of the transparent screen 12 of the display module 10 for inputting and communicating with the electronic device increases the difficult of illegally detecting the inputting signals.

It is worth to mention that the display module 10 is a liquid crystal display (LCD), so that the display module 10 is relatively thinner, smaller, and less consuming of electricity, so as to make the electronic device to be more portable.

The protection layer 31 of the protection element 30 comprises a plurality of conductive wires 311 made by a transparent material such as ITO, intertwining to form a net shaped layer so as to form the protection circuit, wherein the conductive wires 311 of the protection layer 31 is provided to integrally incorporate the display module 10. The conductive wires 311 are integrally affixed at a lower side of the screen panel 11, or an upper side of the screen panel 12, wherein each two of the conductive wires 311 are crossed to each other to form a net shaped area to integrally affix to the lower or upper side of the screen panel 11 of the display module 10. The conductive wires 311 formed the net shaped area of the protection layer 31 is further electrically connected to the detective circuit 22, so that when the display module 10 is being penetrated to hack into the core circuit module 20 of the electronic device, the conductive wires 311 of the protection layer 31 of the protection element 30 automatically activate the detective circuit 22 of the core circuit module 20 to destroy the information being saved in the data unit 23. The conductive wires 311 of the protection layer 31 can also be provided between the screen panel 11 and the transparent screen 12, or integrally provided within the screen panel 11 or the transparent screen 12.

It is appreciated that the conductive wires 311 can also be integrally affixed to a transparent membrane, wherein the transparent membrane having the conductive wires 311 is further adhesive or attached between a top surface and a bottom surface of the display module 10. In other words, the protection layer 31 is sandwiched between the screen panel 11 and the transparent screen 12 of the display module 10. Therefore, the conductive wires 311 can also be activated to connect to the detective circuit 22 when the display module 10 is being penetrated. The protection layer 31 further can be integrally provided within the screen panel 11, the transparent panel 12, between the screen panel 11 and the transparent screen 12, a bottom surface of the display module 10, or a top surface of the display module 10.

It is appreciated that the protection layer 31 can be affixed to the top surface of the transparent screen 12 of the display module 10, as shown in FIG. 1B. Likewise, the protection layer 31 can be affixed to the bottom surface of the screen panel 11 of the display module 10, as shown in FIG. 1C.

It is worth to mention that the net shaped area of the conductive wires 311 of the protection layer 31 has an area equal or larger than the viewable area of the display module 10, in such manner that the protection layer 31 can fully cover the display module 10 so as to fully protect the display module 10 being penetrated to get the information in the data unit 23 of the core circuit module 20.

It is appreciated that the protection layer 31 can also be used and affixed on any protective glasses such as car window, house window, or any different kinds of displays such as LED, LCD television, computer screen, cell phone touch screen.

The protection element 30 further comprises a core element enclosure 32 enclosing the core circuit module 20 to form a protective shield thereof, wherein the protection circuit is formed at an enclosure wall of the core element enclosure 32 for protecting the core circuit module 20 from being hacked through the core element enclosure 32.

Accordingly, the core element enclosure 32 is mounted or bonded to attach on the core circuit module 20. The protection circuit is provided on an enclosure wall of the core element enclosure 32, wherein the circuit layer 34 of the core element enclosure 32 is electrically connecting to the detective circuit 22 of the core circuit module 20, wherein when the core element enclosure 32 is being penetrated or detached from the core circuit module 20 to physically interfere with the protection circuit, the detective circuit 22 is activated to erase the data information in the data unit 23 of the core circuit module 20 of the electronic device.

In particularly, the core element enclosure 32 comprises a circuit layer 34 overlapping at the enclosure wall to form the protection circuit and to operatively link with the detective circuit 22.

Accordingly, the core element enclosure 32 forms a cover to cover on the utilizing area of the core circuit module 20, wherein the CPU 21, the data unit 23, the detective circuit 22 are located at the utilizing area of the core circuit module 20.

The securely data protecting arrangement also comprises an auxiliary enclosure 33, wherein the auxiliary enclosure 33 has a top window coupling with a peripheral of the display module 10, and a bottom opening coupling with the core circuit module 20, so that the auxiliary enclosure 33 integrals the display module 10 and the core circuit module 20 covered by the core element enclosure 32. The auxiliary enclosure 33 has the protection circuit provided on the surface of the auxiliary enclosure 33 to form the circuit layer 34 overlapping on the surface of the auxiliary enclosure 33, wherein the circuit layer 34 is operatively linking between the auxiliary enclosure 33 and the detective circuit 22 of the core circuit module 20, so that when the auxiliary enclosure 33 is penetrated or broken to physically interfere with the protection circuit, the detective circuit 22 is automatically activated to erase or lock the data information in the data unit 23 of the core circuit module 20, in such manner that the auxiliary enclosure 33 provides a further protection of the data information.

According, in order to form the protection circuit for each of the core element enclosure 32 and the auxiliary enclosure 33, each of the core element enclosure 32 and the auxiliary enclosure 33 comprises a plurality of circuit wires 341 intertwining to form the circuit layer 34. In other words, the circuit wires 341 are provided on the enclosure wall of the core element enclosure 32 to form the circuit layer 34 thereof, while the circuit wires 341 are provided on the surface of the auxiliary enclosure 33 to form the circuit layer 34 thereof.

It is appreciated that the circuit layer 34 can be configured as the same as the protection layer 31 that the circuit wires 341 are the same as the conductive wires 311. However, since the circuit wires 341 does not require having the transparent function, the circuit wires 341 can be made of non-transparent conductive material. In addition, the circuit wires 341 can be affixed to the enclosure wall of the core element enclosure 32 and to the surface of the auxiliary enclosure 33 by adhesive. Likewise, the circuit wires 341 can be embedded into the enclosure wall of the core element enclosure 32 and into the surface of the auxiliary enclosure 33 such that each of the core element enclosure 32 and the auxiliary enclosure 33 forms the protection circuit.

It is worth mentioning that the core circuit module 20 are protected by three different protections, i.e. the protection layer 31, the core element enclosure 32, and the auxiliary enclosure 33, for preventing the core circuit module 20 from being hacked physically.

An outer casing 40 is further provided to enclose the core circuit module 20, the display module 10, the core element enclosure 32, and the auxiliary enclosure 33 in a hidden manner, wherein the outer casing 40 can not only provide a decoration for the securely data protecting arrangement, but also provide another protection of the data information of the data unit 23 of the core circuit module 20.

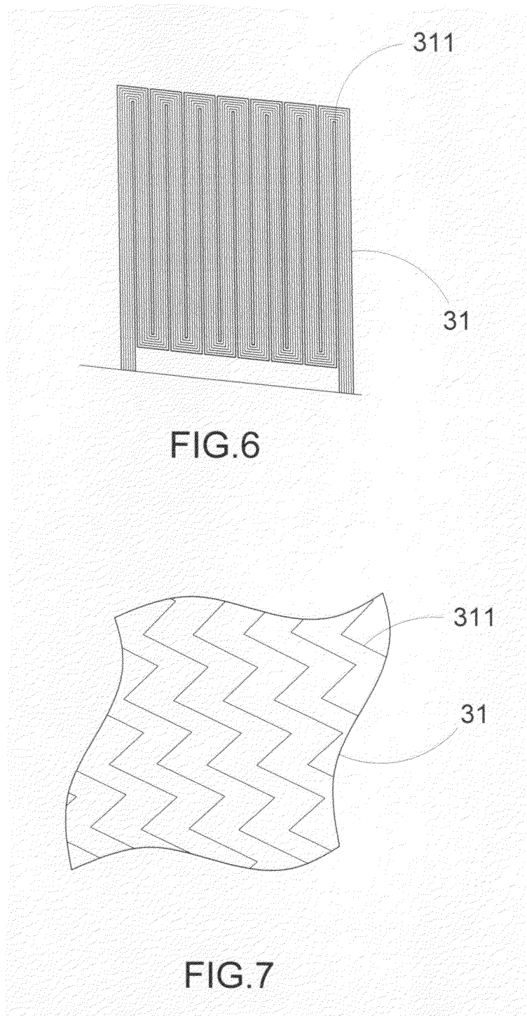

Referring to FIG. 6, a first alternative of a protection layer 31A of the display module 10 of the securely data protecting arrangement according to the above preferred embodiment of the present invention is illustrated, wherein the protection layer 31A has a plurality of conductive wires 311A. Each of the conductive wires 311A is arranged similar to a “Z” shape and any two of the conductive wires 311A are parallel to each other. In order words, each of the conductive wires 311A has a serrate shape to form a net of the protection layer 31A for covering the display module 10.

Referring to FIG. 7, a second alternative of a protection layer 31B of the display module 10 of the securely data protecting arrangement according to the above preferred embodiment of the present invention is illustrated, wherein the protection layer 31B has a conductive wire 311B continuing folded to form a continuing “S” shape to cover the display module 10.

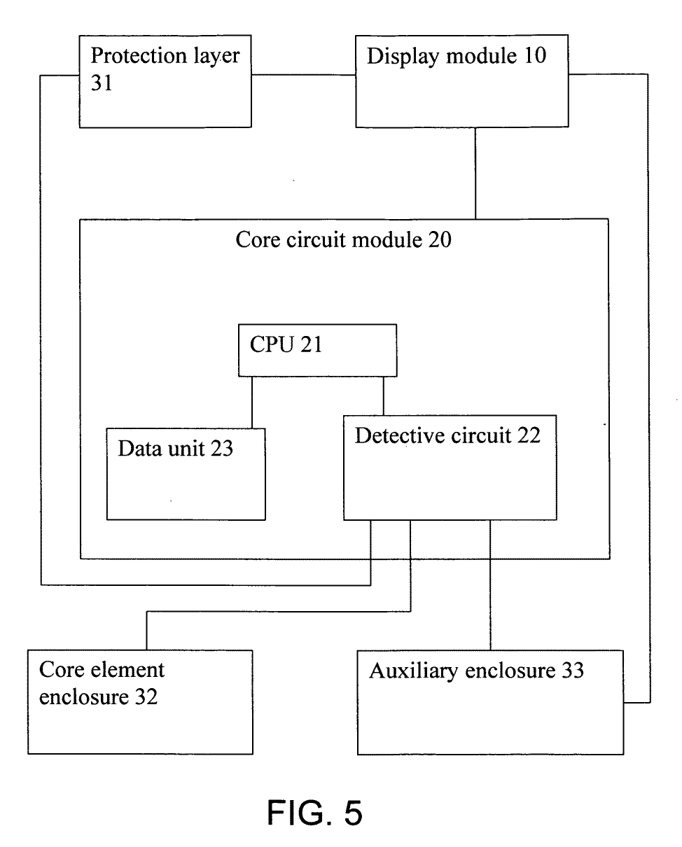

Referring to FIG. 5 of the drawings, a method of securely data protecting arrangement of an electronic device is illustrated, wherein the method comprises:

providing a data unit 23, a detective circuit 22, and a CPU 21 to a core circuit module 20 of the electronic device, wherein the data unit 23, the detective circuit 22, and the CPU 21 are electrically connected to each other; and

electrically connecting a protection element 30 to the core circuit module 20 of the electronic device, so that when the electronic device is hacked to achieve the data information of the core circuit module 20, the protection circuit is physically interfered to activate the detective circuit 22 of the core circuit module 20 to erase a data information saved in the data unit 23 through the CPU 21, so as to protect the data information saved in the data unit 23 of the core circuit module 20.

The method of securely data protecting arrangement also comprises a step of coupling an auxiliary enclosure 33 of the protection element 30 to the display module 10 and the core circuit module 20.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A method of securely data protection for an electronic device, comprising:
(a) enclosing a core circuit module of said electronic device within a protection element to form a protection circuit surrounding said core circuit module;
(b) operatively linking a detective circuit between said protection element and said core circuit module; and
(c) activating said detective circuit in case of a hack of said electronic device, such that when said electronic device is broken to access said core circuit module through said protection element to physically interfere with said protection circuit, said detective circuit is activated to block data information saved in said core circuit module from being access.

2. The method as recited in claim 1 wherein, in the step (a), a transparent protection layer of said protection element is affixed at a position above said core circuit module in incorporate with a display module of said electronic device for protecting said core circuit module from being hacked through said display module.

3. The method, as recited in claim 2, wherein said protection layer comprises a plurality of conductive wires intertwining to form a net shaped layer, having a size at least larger than a viewable area of said display module, overlaying above said core circuit module.

4. The method, as recited in claim 3, wherein said conductive wires are conducted to form said protection circuit for operatively linking with said detective circuit.

5. The method, as recited in claim 3, wherein said protection layer is overlapped on one of a top surface and a bottom surface of said display module.

6. The method, as recited in claim 3, wherein said protection layer is overlapped between a top surface and a bottom surface of said display module.

7. The method as recited in claim 1 wherein, in the step (a), a core element enclosure of said protection element is provided to form a protective shield for enclosing said core circuit module, wherein said protection circuit is formed at an enclosure wall of said core element enclosure for protecting said core circuit module from being hacked through said core element enclosure.

8. The method as recited in claim 3 wherein, in the step (a), a core element enclosure of said protection element is provided to form a protective shield for enclosing said core circuit module, wherein said protection circuit is formed at an enclosure wall of said core element enclosure for protecting said core circuit module from being hacked through said core element enclosure.

9. The method, as recited in claim 7, wherein said core element enclosure comprises a circuit layer overlapping at said enclosure wall to form said protection circuit and to operatively link with said detective circuit.

10. The method, as recited in claim 8, wherein said core element enclosure comprises a circuit layer overlapping at said enclosure wall to form said protection circuit and to operatively link with said detective circuit.

11. The method, as recited in claim 1, further comprising a step of erasing all data information saved in said core circuit module when said detective circuit is activated.

12. The method, as recited in claim 8, further comprising a step of erasing all data information saved in said core circuit module when said detective circuit is activated.

13. The method, as recited in claim 10, further comprising a step of erasing all data information saved in said core circuit module when said detective circuit is activated.

14. An electronic device, comprising:
a core circuit module for saving data information;
a display module operatively connecting to said core circuit module; and
a protection arrangement, which comprises:
a protection element enclosing said core circuit module to form a protection circuit surrounding said core circuit module; and
a detective circuit operatively linking between said protection element and said core circuit module, wherein when said electronic device is broken to access said core circuit module through said protection element, said detective circuit is automatically activated to block data information saved in said core circuit module from being access.

15. The electronic device, as recited in claim 14, wherein said protection element comprises a transparent protection layer affixed at a position above said core circuit module in incorporate with said display module for protecting said core circuit module from being hacked through said display module.

16. The electronic device, as recited in claim 15, wherein said protection layer comprises a plurality of conductive wires intertwining to form a net shaped layer, having a size at least larger than a viewable area of said display module, overlaying above said core circuit module.

17. The electronic device, as recited in claim 16, wherein said conductive wires are conducted to form said protection circuit for operatively linking with said detective circuit.

18. The electronic device, as recited in claim 17, wherein said protection layer is overlapped on one of a top surface and a bottom surface of said display module.

19. The electronic device, as recited in claim 17, wherein said protection layer is overlapped between a top surface and a bottom surface of said display module.

20. The electronic device, as recited in claim 14, wherein said protection element comprises a core element enclosure enclosing said core circuit module to form a protective shield thereof, wherein said protection circuit is formed at an enclosure wall of said core element enclosure for protecting said core circuit module from being hacked through said core element enclosure.

21. The electronic device, as recited in claim 17, wherein said protection element comprises a core element enclosure enclosing said core circuit module to form a protective shield thereof, wherein said protection circuit is formed at an enclosure wall of said core element enclosure for protecting said core circuit module from being hacked through said core element enclosure.

22. The electronic device, as recited in claim 20, wherein said core element enclosure comprises a circuit layer overlapping at said enclosure wall to form said protection circuit and to operatively link with said detective circuit.

23. The electronic device, as recited in claim 21, wherein said core element enclosure comprises a circuit layer overlapping at said enclosure wall to form said protection circuit and to operatively link with said detective circuit.

24. The electronic device, as recited in claim 14, wherein said detective circuit is electrically coupled with said core circuit module as one integral component, and is a data erasing circuit that when said detective circuit is activated, said data information saved in said core circuit module is automatically erased.

25. The electronic device, as recited in claim 17, wherein said detective circuit is electrically coupled with said core circuit module as one integral component, and is a data erasing circuit that when said detective circuit is activated, said data information saved in said core circuit module is automatically erased.

26. The electronic device, as recited in claim 23, wherein said detective circuit is electrically coupled with said core circuit module as one integral component, and is a data erasing circuit that when said detective circuit is activated, said data information saved in said core circuit module is automatically erased.
